(19) United States
(12) Patent Application Publication
(10) Pub. No.: US 2026/0168082 A1
(43) Pub. Date: Jun. 18, 2026

(54) MASKING AGENT FOR HIGH-DIELECTRIC CONSTANT THIN FILMS, METHOD OF DEPOSITING SELECTED AREA USING MASKING AGENT, SEMICONDUCTOR SUBSTRATE FABRICATED USING METHOD, AND SEMICONDUCTOR DEVICE INCLUDING SEMICONDUCTOR SUBSTRATE

(71) Applicant: SOULBRAIN CO., LTD., Gyeonggi-do (KR)

(72) Inventors: Seung Hyun LEE, Gyeonggi-do (KR); Chang Bong YEON, Gyeonggi-do (KR); Jae Sun JUNG, Gyeonggi-do (KR)

(21) Appl. No.: 18/707,393

(22) PCT Filed: Nov. 18, 2022
(86) PCT No.: PCT/KR2022/018272

§ 371 Date: May 3, 2024

(30) Foreign Application Priority Data
Nov. 26, 2021 (KR) 10-2021-0165388
Oct. 27, 2022 (KR) 10-2022-0140239

(51) Int. Cl. C23C 16/04; C23C 16/40; C23C 16/455; H10P 14/61

(52) U.S. Cl. CPC C23C 16/042; C23C 16/405; C23C 16/45553; H10P 14/61

(57) ABSTRACT

The present invention relates to a masking agent for high-dielectric constant thin films, a method of depositing a selected region using the masking agent, a semiconductor substrate fabricated using the method, and a semiconductor device including the semiconductor substrate. More particularly, the present invention relates to a masking agent for high-dielectric constant thin films that is capable of producing a thin film with a pattern formed by atomic layer deposition without performing a patterning process and is capable of significantly reducing impurities, a method of depositing a selected region using the masking agent, a semiconductor substrate fabricated using the method, and a semiconductor device including the semiconductor substrate.

### TECHNICAL FIELD

The present invention relates to a masking agent for high-dielectric constant thin films, a method of depositing a selected region using the masking agent, a semiconductor substrate fabricated using the method, and a semiconductor device including the semiconductor substrate. More particularly, the present invention relates to a masking agent for high-dielectric constant thin films that is capable of producing a thin film with a pattern formed by atomic layer deposition without performing a patterning process and is capable of significantly reducing impurities, a method of depositing selected region using the masking agent, a semiconductor substrate fabricated using the method, and a semiconductor device including the semiconductor substrate.

### BACKGROUND ART

Since metals, semiconductors, or insulator thin films are used in various s fields such as semiconductor devices, integrated circuits, solar cells, liquid crystal displays, and organic light-emitting diodes, semiconductor processing is necessary.

In the semiconductor processing, an etching-deposition-polishing (CMP) process is repeatedly performed to selectively deposit films on a complex surface made by bonding various materials.

Research is being actively conducted to deposit high-quality thin films at relatively low temperatures using atomic layer deposition (ALD), which controls the deposition reaction mechanism.

In the ALD process, the surface environment of a substrate is gradually adjusted to form a self-saturated unit atomic film raw material, and a reaction occurs on the surface. Due to the nature of self-saturated raw material formation, the thickness of an atomic unit can be adjusted. In addition, even when a surface of a very complex shape is formed by surface movement of a raw material precursor, a perfectly homogeneous thin film can be deposited, the density of the deposited thin film can be increased, and the deposition temperature can be reduced.

In recent years, along with the miniaturization of semiconductor patterns, three-dimensionalization has progressed, making it difficult to form structural parts using conventional techniques.

To overcome these problems, there is a need for the development of ‘selective deposition technology’, which selectively deposits and laminates thin films only in regions where specific components are needed.

Selective deposition can be classified into an active type, in which a precursor enters a required region, and a passive type, in which an unnecessary region, such as molecular layer-photoresisting, is covered.

Among the types, the active type has the disadvantage of low substrate selectivity, so the use of the passive type is necessary to implement high stack.

The passive type is being developed by permanently-molecular-layer-photoresisting of a substrate through a wet process. For example, there is a technique of immersion in a thiol solution, but it is unsuitable for use in a deposition process due to the disadvantage of wet stripping.

### RELATED ART DOCUMENTS

### Patent Documents

(Patent Document 1) KR 2019-0140104 A

### DISCLOSURE

### Technical Problem

Therefore, the present invention has been made in view of the above problems, and it is one object of the present invention to provide a masking agent for high-dielectric constant thin films, a method of depositing a selected region using the masking agent, a semiconductor substrate fabricated using the method, and a semiconductor device including the semiconductor substrate. According to the present invention, the present invention may provide a selective deposition technology that uses a masking agent for high-dielectric constant thin films to passivate a surface on which the masking agent has not grown by performing dry removal-molecular layer-photoresisting for each deposition cycle and apply a precursor only to a surface on which the masking agent is grown.

The above and other objects can be accomplished by the present invention described below.

### Technical Solution

In accordance with one aspect of the present invention, provided is a masking agent for high-dielectric constant thin films, wherein, on a complex substrate having one or more surfaces having a dielectric constant (k) of less than 4.0 and one or more surfaces having a dielectric constant of 4.0 or more, the masking agent is selectively adsorbed on the surfaces having a dielectric constant of 4.0 or more.

In accordance with another aspect of the present invention, provided is a method of depositing a selected region including:
preparing, on a substrate, a complex substrate having one or more surfaces having a dielectric constant (k) of less than 4.0 and one or more surfaces having a dielectric constant of 4.0 or more; and

loading the substrate into a chamber and then using the masking agent for high-dielectric constant thin films according to claim 1, a precursor compound, and a reaction gas to provide a step pattern or stack in which a deposition thickness of the surfaces having a dielectric constant (k) of less than 4.0 to a deposition thickness of the surfaces having a dielectric constant (k) of 4.0 or more is within a range of 1:2 to 20 by the masking agent for high-dielectric constant thin films.

In accordance with still another aspect of the present invention, provided is a method of depositing a selected region including injecting the masking agent for high-dielectric constant thin films into a chamber to inject the masking agent onto a substrate surface loaded into the chamber.

In accordance with still another aspect of the present invention, provided is a semiconductor substrate including the step pattern or stack manufactured by the method of depositing a selected region.

In accordance with yet another aspect of the present invention, provided is a semiconductor device including the semiconductor substrate.

The semiconductor substrate may be low resistive metal gate interconnects, a high aspect ratio 3D metal-insulator-metal (MIM) capacitor, a DRAM trench capacitor, 3D Gate-All-Around (GAA), or 3D NAND.

### Advantageous Effects

According to the present invention, a step pattern or a stack can be formed without performing a patterning process. In addition, the present invention has the effect of providing a selective deposition region on a substrate with a complex structure by controlling a thin film growth rate.

In addition, process by-products are more effectively reduced when forming a thin film, preventing corrosion or deterioration and improving the crystallinity of the thin film, thereby improving the electrical properties of the thin film.

In addition, when forming a thin film, process by-products are reduced and step coverage and thin film density can be improved. Furthermore, the present invention has the effect of providing a method of depositing a selected region using a masking agent and a semiconductor substrate fabricated using the method.

### DESCRIPTION OF DRAWINGS

FIG. 1 shows a pattern part where two or more types of film materials are revealed on a wafer using a stage heater at a temperature of 300 to 400° C., and is a cross-sectional view showing a lamination thickness of SiO₂ deposited when depositing a total of four types of thin films, SiO₂, HfO₂, ZrO₂, and SiN, and then depositing SiO₂ directly on top of each thin film.

FIG. 2 shows a pattern part where two or more types of film materials are revealed on a wafer using a stage heater at a temperature of 300 to 400° C., and is a cross-sectional view showing a lamination thickness of SiO₂ deposited when depositing a total of four types of thin films, SiO₂, HfO₂, ZrO₂, and SiN, and then depositing SiO₂ directly on top of each thin film.

FIG. 3 is a graph showing deposition rate reduction rates depending on deposition temperatures when HfO₂ of FIG. 2 is deposited depending on whether a masking agent for high-dielectric constant thin films is used.

FIGS. 4 and 5 are graphs showing deposition rate reduction rates depending on deposition temperatures when SiO₂ of FIG. 2 is deposited depending on whether a masking agent for high-dielectric constant thin films is used.

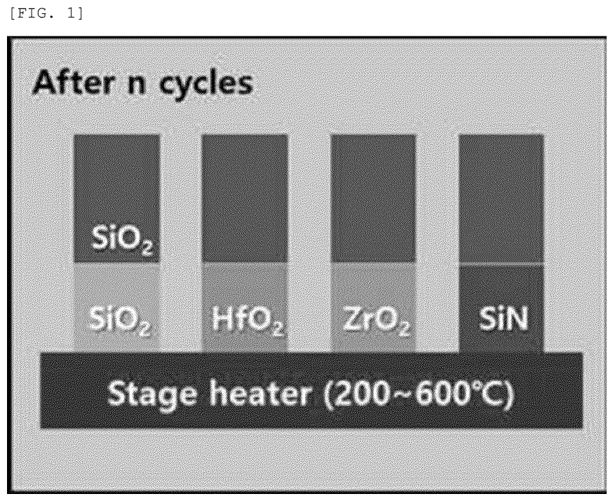

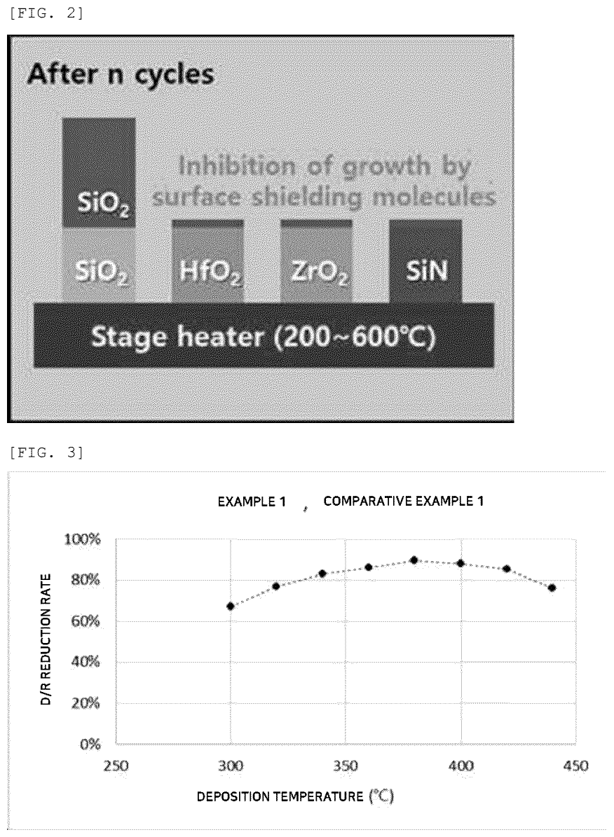

### BEST MODE

Hereinafter, a masking agent for high-dielectric constant thin films according to the present invention, a method of depositing a selected region using the masking agent, and a semiconductor substrate fabricated using the method are described in detail.

The term “high dielectric constant” used in the present invention refers to a dielectric constant (k) of 4.0 or more, unless otherwise specified.

Unless otherwise specified, the term “complex substrate” used in the present invention refers to a substrate having one or more surfaces having a dielectric constant (k) of less than 4.0 and one or more surfaces having a dielectric constant of 4.0 or more.

To achieve the purpose, the present invention provides a masking agent for high-dielectric constant thin films. According to the present invention, on a complex substrate having one or more surfaces having a dielectric constant (k) of less than 4.0 and one or more surfaces having a dielectric constant of 4.0 or more, the masking agent is selectively adsorbed on the surfaces having a dielectric constant of 4.0 or more.

In the complex substrate, the surfaces having a dielectric constant (k) of less than 4.0 may include one or more selected from Si and SiO₂.

In the complex substrate, the surfaces having a dielectric constant (k) of 4.0 or more may be expressed as MO₂, M₂O₃, MN, or M₃N₄ (M is metal).

In the complex substrate, the surfaces having a dielectric constant (k) of 4.0 or more may include one or more selected from Al₂O₃, ZrO₂, HfO₂, La₂O₃, Si₃N₄, TiN, TAN, GAN, AlN, and BN.

When an adsorption selectivity to the surfaces having a dielectric constant (k) of less than 4.0 is designated as a, and an adsorption selectivity to the surfaces having a dielectric constant of 4.0 or more is designated as b, the masking agent may satisfy Equation 1 below.

$$a < b < 2 a \qquad [ Equation 1 ]$$

The masking agent for high-dielectric constant thin films may be a compound deposited at a thickness of 0.1 to 0.4 Å per cycle on a surface with a dielectric constant (k) of 4.0 or more.

The masking agent for high-dielectric constant thin films may be a compound deposited at a thickness of 0.6 to 1.5 Å per cycle on a surface with a dielectric constant (k) of less than 4.0.

The dielectric constant (k) used in the present invention may be based on a value (measured at 20° C.) known in the art.

The masking agent for high-dielectric constant thin films that satisfies the above-described deposition thickness may be a compound having a tertiary structure or a linear carbonate structure.

The masking agent for high-dielectric constant thin films may preferably include one or more compounds selected from linear compounds having three or more elemental species having unshared pair electrons.

The linear compound having three or more elemental species having unshared pair electrons may be a compound represented by Chemical Formula 1 below.

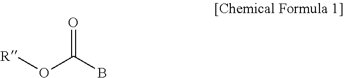

In Chemical Formula 1, R″ is hydrogen, an alkyl group having 1 to 5 carbon atoms, an alkene group having 1 to 5 carbon atoms, or an alkoxy group having 1 to 5 carbon atoms, and

B is —OH, —OCH₃, —OCH₂CH₃, —CH₂CH₃, —SH, —SCH₃, or —SCH₂CH₃.

The masking agent for high-dielectric constant thin films may have a refractive index (measured at 20 to 25° C.) of 1.365 to 1.48, 1.366 to 1.47, 1.367 to 1.46, 1.365 to 1.41, or 1.41 to 1.46.

The masking agent for high-dielectric constant thin films may include one or more selected from compounds represented by Chemical Formulas 1-1 to 1-3 below.

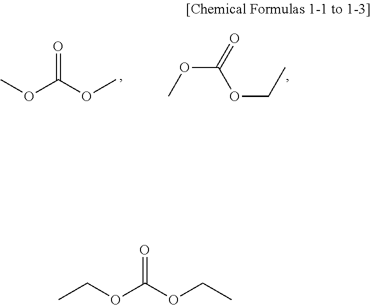

The masking agent for high-dielectric constant thin films may be solid or liquid under conditions of 20° C. and 1 bar.

In addition, the present invention provides a method of depositing a selected region including:
a step of preparing, on a substrate, a complex substrate having one or more surfaces having a dielectric constant (k) of less than 4.0 and one or more surfaces having a dielectric constant of 4.0 or more; and

a step of loading the substrate into a chamber and then using the masking agent for high-dielectric constant thin films according to claim 1, a precursor compound, and a reaction gas to provide a step pattern or stack in which a deposition thickness of the surfaces having a dielectric constant (k) of less than 4.0 to a deposition thickness of the surfaces having a dielectric constant (k) of 4.0 or more is within a range of 1:2 to 20 by the masking agent for high-dielectric constant thin films.

On the surfaces having a dielectric constant (k) of 4.0 or more, the deposition thickness of the surfaces having a dielectric constant (k) of less than 4.0 may be 0.1 to 0.4 Å per cycle by the masking agent for high-dielectric constant thin films.

On the surfaces having a dielectric constant (k) of less than 4.0, the deposition thickness of the surfaces having a dielectric constant (k) of less than 4.0 may be 0.6 to 1.5 Å per cycle by the masking agent for high-dielectric constant thin films.

The substrate may be formed from a hafnium-based thin film, a silicon-based thin film, an aluminum-based thin film, a copper thin film, and a tungsten thin film.

The hafnium-based thin film may be hafnium oxide.

The silicon-based thin film may be silicon nitride or silicon oxide.

The aluminum-based thin film may be aluminum oxide.

At this time, the substrate may be selected from titanium nitride, hafnium oxide, silicon oxide, or silicon nitride, depending on need.

The method of depositing a selected region may be performed by ALD, CVD, PEALD or PECVD.

A precursor compound providing the surfaces having a dielectric constant of 4.0 or more may be a molecule made up of a central metal forming Si₃N₄, Al₂O₃, TiO₂, Ta₂O₅, HfO₂, ZrO₂, La₂O₃, Gd₂O₃, Er₂O₃, Nd₂O₃, PrO₂, CeO₂, Y₂O₃, HfSiO₂, a-LaAlO₃, SrTiO₃ or the like.

The lower substrate of the complex substrate may be selected from SiN, SiO₂, HfO, Al₂O₃, Cu, and W.

The reaction gas may contain oxygen, nitrogen, or sulfur.

The deposition temperature may be 50 to 700° C.

In addition, the present invention provides a method of depositing a selected region including a step of injecting the masking agent for high-dielectric constant thin films into a chamber to inject the masking agent onto a substate loaded into the chamber.

The method of depositing a selected region may include step i-a) of forming a shielding region on the surface of the substrate loaded into the chamber by vaporizing the masking agent for high-dielectric constant thin films; step i-b) of first-purging inside of the chamber using a purge gas; step ii-a) of vaporizing a raw material precursor for a target membrane and adsorbing the raw material precursor to a region outside the shielding region; step ii-b) of second-purging the inside of the chamber using a purge gas; step iii-a) of vaporizing a raw material precursor for a non-target membrane and adsorbing the raw material precursor to a region outside the shielding region; step iii-b) of third-purging the inside of the chamber using a purge gas; step iv-a) of supplying a reaction gas into the chamber; and step iv-b) of fourth-purging the inside of the chamber using a purge gas.

Steps iii-a) and iii-b) may be performed prior to steps ii-a) and ii-b), and when necessary, steps ii-a) and iii-a) and steps ii-b) and steps iii-b) may be performed simultaneously.

In addition, steps iii-a) and iii-b) may be performed before steps ii-a) and ii-b), and then steps i-a) and i-b) may be performed, and when necessary, steps ii-a) and iii-a) and steps ii-b) and iii-b) may be performed simultaneously, and then steps i-a) and i-b) may be performed.

The chamber may be an ALD chamber, a CVD chamber, a PEALD chamber, or a PECVD chamber.

The masking agent for high-dielectric constant thin films or the raw material precursor may be vaporized, injected, and then subjected to plasma post-treatment.

The amount of the purge gas introduced into the chamber may be 10 to 100,000 times the volume of the masking agent for high-dielectric constant thin films.

The reaction gas, the masking agent for high-dielectric constant thin films, and the raw material precursor may be introduced into the chamber by a VFC method, a DLI method or an LDS method.

The substrate loaded into the chamber may be heated to 50 to 400° C., and the input ratio (mg/cycle) of the masking agent for high-dielectric constant thin films and the raw material precursor in the chamber is 1:1.5 to 1:20.

The reaction gas may be a reducing agent, a nitriding agent, or an oxidizing agent.

In the method of depositing a selected region, the deposition temperature may be 50 to 700° C.

The thin film for selective atomic layer deposition may be a low-dielectric constant thin film, a high-dielectric constant thin film, or a metal film.

In addition, the present invention provides a semiconductor substrate including a step pattern or stack manufactured by the method of depositing a selected region.

The step pattern or stack may have a multi-layered structure of two or three layers or more.

The step pattern or the stack does not remain in the hafnium-based thin film, silicon-based thin film, aluminum-based thin film, copper thin film, or tungsten thin film, and may contain carbon, silicon, and halogen compounds in an amount of less than 1%.

The step pattern or the stack may be used in an insulator, a dielectric film, a diffusion barrier, or an electrode.

In addition, the present invention provides a semiconductor device including the above-described semiconductor substrate.

The semiconductor substrate may be low resistive metal gate interconnects, a high aspect ratio 3D metal-insulator-metal (MIM) capacitor, a DRAM trench capacitor, 3D Gate-All-Around (GAA), or 3D NAND.

According to the present invention, a step pattern or a stack may be formed without performing a patterning process. In addition, the present invention has the effect of providing a selective deposition region on a substrate with a complex structure by controlling a thin film growth rate.

In addition, process by-products are more effectively reduced when forming a thin film, preventing corrosion or deterioration and improving the crystallinity of the thin film, thereby improving the electrical properties of the thin film.

In addition, when forming a thin film, process by-products are reduced and step coverage and thin film density may be improved. Furthermore, the present invention has the effect of providing a method of depositing a selected region using a masking agent and a semiconductor substrate fabricated using the method.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Example 1 and Comparative Examples 1 and 2

Masking agents for high-dielectric constant thin films, raw material precursors, reaction gases, deposition temperatures, flow rates, purge and deposition conditions, and cycle conditions (masking agent injection-purge-precursor injection-purge-reaction gas injection-purge) to be used in the experiment are shown in Table 1.

TABLE 1

| | | | | | | Input |
|---|---|---|---|---|---|---|
| | | | | | | time of |
| | | | | | | masking |
| | | Masking | | | | agent for |
| | | agent for | | | | high- |
| | | high- | | | | dielectric |
| | | dielectric | | | | constant |
| | Raw | constant | | | Deposition | thin |
| | material | thin | Reaction | Flow | temperature | films |
| Classification | precursor | films | gas | (sccm) | (° C.) | (sec) |
| Example 1 | CpHf | Chemical | O₃ | 500 | 300~400 | 1 |
| | | Formula | | | | |
| | | 1-1 | | | | |
| Comparative | CpHf | — | O₃ | 500 | 300~400 | — |
| Example 1 | | | | | | |
| Comparative | BTBAS | Chemical | O₃ | 1000 | 250~600 | 1 |
| Example 2 | | Formula | | | | |
| | | 1-1 | | | | |
| Comparative | BTBAS | — | O₃ | 1000 | 250~600 | — |
| Example 3 | | | | | | |
| Comparative | 3DMAS | Chemical | O₃ | 1000 | 250~600 | 1 |
| Example 4 | | Formula | | | | |
| | | 1-1 | | | | |
| Comparative | 3DMAS | — | O₃ | 1000 | 250~600 | — |
| Example 5 | | | | | | |

In Table 1, CpHf is an abbreviation for CpHf(NMe₂)₃, BTBAS is an abbreviation for [bis(tertiarybutylamino) silane], and 3DMAS is an abbreviation for tris(dimethylamino)silane.

The experiment was performed as follows using the combinations shown in Table 1.

Specifically, a compound represented by Chemical Formula 1-1 below was prepared as a high-dielectric constant thin film masking agent.

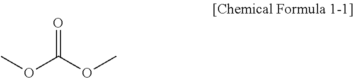

In addition, CpHf, BTBAS, and 3DMAS were prepared as precursors, and ozone (ozone with a concentration of 200 g per m³ of oxygen) was prepared as a reaction gas.

### Example 1

The masking agent for high-dielectric constant thin films was placed in a canister and supplied to a vaporizer heated to 150° C. at a flow rate of 0.2 g/min using a liquid mass flow controller (LMFC) at room temperature. The masking agent for high-dielectric constant thin films, which was vaporized in a vaporizer, was introduced into a deposition chamber loaded with a substrate for 1 second, and then argon gas was supplied at 3000 sccm for 2 seconds to perform argon purging. At this time, the pressure within the reaction chamber was controlled at 2 Torr.

Subsequently, the precursor compound CpHf was placed in a canister and injected into the chamber for 1 second through a vapor flow controller (VFC), and argon purging was performed by supplying argon gas at 3000 sccm for 2 seconds. At this time, the pressure within the reaction chamber was controlled at 2 Torr.

Next, 1000 sccm of ozone as a reactive gas was introduced into the reaction chamber for 3 seconds, and then argon purging was performed for 3 seconds. At this time, the substrate on which a thin film was to be formed was heated under the temperature conditions shown in Table 1.

This process was repeated 200 to 400 times to form a self-limiting atomic layer thin film with a thickness of 10 nm.

### Comparative Examples 1 to 5

The same process as in Example 1 was repeated using the materials and conditions according to Table 1 except that the masking agent for high-dielectric constant thin films was not used.

### Test Example 1

For thin films obtained in Example 1 and Comparative Examples 1 to 5, the deposition rate reduction rate (D/R reduction rate), SIMS C impurities, and step coverage were measured in the following manner, and the results are shown in FIGS. 3 to 5.
Deposition rate reduction rate (D/R (dep. rate) reduction rate): The deposition rate reduction rate refers to a rate at which a deposition rate is reduced after adding a shielding material compared to the D/R before adding a thin film shielding material that reacts on an activated surface, and was calculated as a percentage using each measured A/cycle value.

The thickness of the manufactured thin film was measured using an ellipsometer, which is used to measure optical properties such as the thickness of a thin film or refractive index using the polarization characteristics of light. The deposition rate was calculated by dividing the measured thin film thickness by the number of cycles to calculate the thickness of the thin film deposited per cycle. Specifically, Equation 1 below was used.

$$Deposition rate ( D / R ) = Thickness of deposited thin film / number of deposition cycles \qquad [ Equation 1 ]$$

Secondary-ion mass spectrometry (SIMS) C impurities: C impurities values were confirmed in an SIMS graph by considering the C impurities content (counts) at a sputter time of 50 seconds, when the thin film was dug in the axial direction with an ion sputter and there was little contamination in the surface layer of the substrate.
Step coverage (%): For the thin films deposited according to Example 1 and Comparative Examples 1 to 5 on a complex structure substrate with an aspect ratio of 22:1, positions 100 nm down from the top (left drawing) and 100 nm up from the bottom (right drawing) were horizontally cut, and the cut specimen was analyzed with TEM to calculate the step coverage.

Specifically, the deposition process was performed using diffusion improving material application conditions on a complex structure substrate having an upper diameter of 90 nm, a lower diameter of 65 nm, a via hole depth of approximately 2000 nm, and an aspect ratio of 22:1. Then, to confirm the deposition thickness uniformity and step coverage inside the vertically formed via hole, a specimen was obtained by cutting horizontally at 100 nm from the top and 100 nm from the bottom, and transmission electron microscopy (TEM) analysis was performed.

### Additional Example 1

The region an Si substrate was divided, and the same process as Example 1 and Comparative Example 1 was performed, respectively, to obtain a thin film on which HfO₂ was deposited depending on whether the masking agent for high-dielectric constant thin films was used.

The deposition rate reduction rate of the corresponding thin film was calculated for each deposition temperature between the region to which Example 1 was applied and the region to which Comparative Example 1 was applied, and the results are shown in FIG. 3 below.

As shown in FIG. 3, the deposition rate (D/R) of Example 1 in which the masking agent for high-dielectric constant thin films according to the present invention was applied to a surface having a dielectric constant (k) of 4.0 or more was significantly improved compared to Comparative Example 1 in which the masking agent for high-dielectric constant thin films was not used.

### Additional Comparative Example 1

The same method as Additional Example 1 was performed, and the same process as Additional Example 1 was repeated to obtain a thin film on which SiO₂ was deposited depending on whether the masking agent for high-dielectric constant thin films was used, except that, instead of Example 1, the same process as Comparative Example 2 was performed, and instead of Comparative Example 1, the same process as Comparative Example 3 was performed.

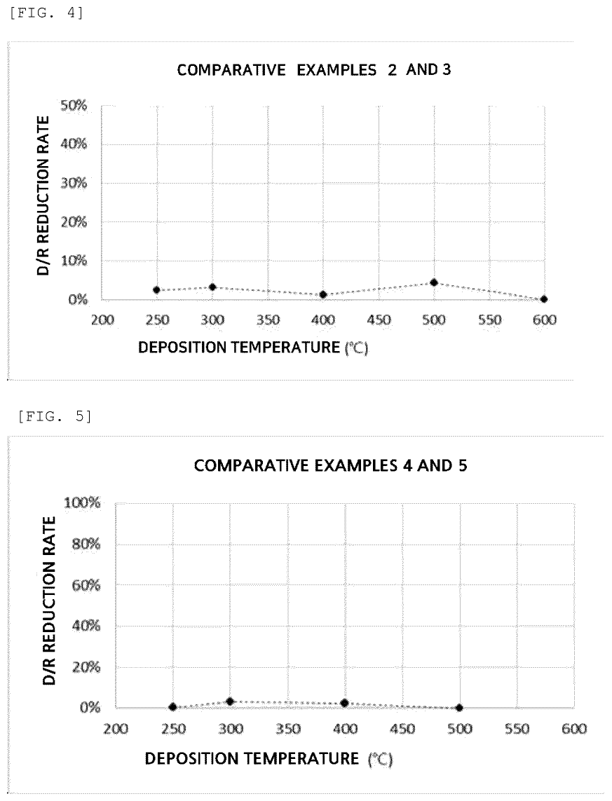

The deposition rate reduction rate of the thin film was calculated for each deposition temperature between the region to which Comparative Example 2 was applied and the region to which Comparative Example 3 was applied, and the results are shown in FIG. 4 below.

As shown in FIG. 4, Comparative Example 2 in which the masking agent for high-dielectric constant thin films according to the present invention was applied to a surface having a dielectric constant (k) of less than 4.0 did not show improvement in the reduction rate of deposition rate (D/R) compared to Comparative Example 3 in which the masking agent for high-dielectric constant thin films was not used.

### Additional Comparative Example 2

The same method as Additional Example 1 was performed, and the same process as Additional Example 1 was repeated to obtain a thin film on which SiO₂ was deposited depending on whether the masking agent for high-dielectric constant thin films was used, except that, instead of Example 1, the same process as Comparative Example 4 was performed, and instead of Comparative Example 1, the same process as Comparative Example 5 was performed.

The deposition rate reduction rate of the thin film was calculated for each deposition temperature between the region to which Comparative Example 4 was applied and the region to which Comparative Example 5 was applied, and the results are shown in FIG. 5 below.

As shown in FIG. 5, Comparative Example 4 in which the masking agent for high-dielectric constant thin films according to the present invention was applied to a surface having a dielectric constant (k) of less than 4.0 did not show improvement in the reduction rate of deposition rate (D/R) compared to Comparative Example 5 in which the masking agent for high-dielectric constant thin films was not used.

### Test Example 2

In the graphs showing deposition rate reduction rates for each deposition temperature of FIGS. 3 to 5, the deposition rate reduction rates at a deposition temperature of 400° C. are summarized in Table 2 below.

TABLE 2

| | | | Deposition | | |
|---|---|---|---|---|---|
| Additional | Experi- | | temper- | D/R | D/R |
| Experimental | mental | Reaction | ature | (Å/ | reduction |
| Examples | example | surface | (° C.) | cycle) | rate |
| Additional | Example1 | HfO₂ | 400 | 0.10 | 88% |
| Example 1 | Comparative | HfO₂ | 400 | 0.85 | |
| | Example1 | | | | |
| Additional | Comparative | SiO₂ | 400 | 0.85 | 1% |
| Comparative | Example2 | | | | |
| Example 1 | Comparative | SiO₂ | 400 | 0.84 | |
| | Example3 | | | | |
| Additional | Comparative | SiO₂ | 400 | 0.45 | 2% |
| Comparative | Example4 | | | | |
| Example 2 | Comparative | SiO₂ | 400 | 0.44 | |
| | Example5 | | | | |

As shown in Additional Example 1 of Table 2, the deposition rate reduction rate between Example 1 in which the masking agent for high-dielectric constant thin films according to the present invention was applied to a surface having a dielectric constant (k) of 4.0 or more and Comparative Example 1 in which the masking agent for high-dielectric constant thin films was not applied to the corresponding surface reached 88%.

On the other hand, as shown in Additional Comparative Example 2 of Table 2, the deposition rate reduction rate between Comparative Example 2 in which the masking agent for high-dielectric constant thin films was applied to a surface having a dielectric constant (k) of less than 4.0 and Comparative Example 3 in which the masking agent for high-dielectric constant thin films was not applied to the corresponding surface was only 1%.

In addition, as shown in Additional Comparative Example 3 of Table 2, the deposition rate reduction rate between Comparative Example 4 in which the masking agent for high-dielectric constant thin films was applied to a surface having a dielectric constant (k) of less than 4.0 and Comparative Example 5 in which the masking agent for high-dielectric constant thin films was not applied to the corresponding surface was only 2%.

Therefore, according to the present invention, a selective deposition technology that uses a masking agent for high-dielectric constant thin films to passivate a surface on which the masking agent has not grown by performing dry removal-molecular layer-photoresisting for each deposition cycle and apply a precursor only to a surface on which the masking agent is grown may be effectively performed. The present invention is suitable for providing various semiconductor substrates and semiconductor devices.

1. A masking agent for high-dielectric constant thin films, wherein, on a complex substrate having one or more surfaces having a dielectric constant (k) of less than 4.0 and one or more surfaces having a dielectric constant of 4.0 or more, the masking agent is selectively adsorbed on the surfaces having a dielectric constant of 4.0 or more.

2. The masking agent according to claim 1, wherein, in the complex substrate, the surfaces having a dielectric constant (k) of less than 4.0 comprise one or more selected from Si and SiO₂.

3. The masking agent according to claim 1, wherein, in the complex substrate, the surfaces having a dielectric constant (k) of 4.0 or more are expressed as MO₂, M₂O₃, MN, or M₃N₄ (M is metal).

4. The masking agent according to claim 3, wherein, in the complex substrate, the surfaces having a dielectric constant (k) of 4.0 or more comprise one or more selected from Al₂O₃, ZrO₂, HfO₂, La₂O₃, Si₃N₄, TiN, TaN, GaN, AlN, and BN.

5. The masking agent according to claim 1, wherein, when an adsorption selectivity to the surfaces having a dielectric constant (k) of less than 4.0 is designated as a, and an adsorption selectivity to the surfaces having a dielectric constant of 4.0 or more is designated as b, the masking agent satisfies Equation 1 below.
$$a < b < 2 a \qquad [ Equation 1 ]$$

6. The masking agent according to claim 1, wherein the masking agent for high-dielectric constant thin films is a compound having a tert-alkyl structure or linear carbonate structure.

7. The masking agent according to claim 1, wherein the masking agent for high-dielectric constant thin films is a compound represented by Chemical Formula 1 below. 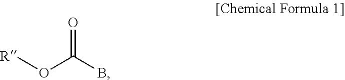
wherein R″ is hydrogen, an alkyl group having 1 to 5 carbon atoms, an alkene group having 1 to 5 carbon atoms, or an alkoxy group having 1 to 5 carbon atoms, and B is —OH, —OCH₃, —OCH₂CH₃, —CH₂CH₃, —SH, —SCH₃, or —SCH₂CH₃.

8. A method of depositing a selected region, comprising:
preparing, on a substrate, a complex substrate having one or more surfaces having a dielectric constant (k) of less than 4.0 and one or more surfaces having a dielectric constant of 4.0 or more; and
loading the substrate into a chamber and then using the masking agent for high-dielectric constant thin films according to claim 1, a precursor compound, and a reaction gas to provide a step pattern or stack in which a deposition thickness of the surfaces having a dielectric constant (k) of less than 4.0 to a deposition thickness of the surfaces having a dielectric constant (k) of 4.0 or more is within a range of 1:2 to 20 by the masking agent for high-dielectric constant thin films.

9. The method according to claim 8, wherein the method is performed by ALD, CVD, PEALD, or PECVD.

10. The method according to claim 8, wherein the precursor compound is independently selected from Ti-based compounds, Hf-based compounds, and Si-based compounds.

11. The method according to claim 8, wherein the deposition temperature is within a range of 50 to 700° C.

12. A semiconductor substrate comprising the step pattern or stack manufactured by the method according to claim 8.

13. The semiconductor substrate according to claim 12, wherein the step pattern or stack has a multi-layered structure of two or three layers or more.

14. A semiconductor device comprising the semiconductor substrate according to claim 12.
